(19) United States
(12) Patent Application Publication
(10) Pub. No.: US 2009/0134494 A1
(43) Pub. Date: May 28, 2009

(54) SEMICONDUCTOR DEVICE AND METHOD OF MANUFACTURING THE SAME

(75) Inventor: Masashi Funakoshi, Osaka (JP)

Correspondence Address: HAMRE, SCHUMANN, MUELLER & LARSON P.C., P.O. BOX 2902-0902, MINNEAPOLIS, MN, 55402, US

(73) Assignee: PANASONIC CORPORATION, Osaka (JP)

(21) Appl. No.: 12/274,590

(22) Filed: Nov. 20, 2008

(30) Foreign Application Priority Data
Nov. 27, 2007 (JP) 2007-306112

(51) Int. Cl. H01L 23/58; H01L 21/58

(52) U.S. Cl. 257/620; 438/114; 257/E23.002; 257/E21.505

(57) ABSTRACT

The present invention includes: a semiconductor element 1 including a circuit forming portion 11 formed on a central region of a principal surface of the semiconductor element 1 and a plurality of electrode pads 8 arranged on the principal surface outside the circuit forming portion 11; an interposer 3 on which the semiconductor element 1 is mounted, terminals 9 arranged on the interposer 3, thin metal wires for electrically connecting the electrode pads 8 and the terminals 9; and a sealing insulator for sealing the semiconductor element 1 and the thin metal wires 5. The present invention further includes a protective sheet 2 formed on the principal surface of the semiconductor element 1 so as to cover the circuit forming portion 11 and at least some of the plurality of electrodes pads 8. With this configuration, it is possible to provide a semiconductor device in which a stress applied to the semiconductor element can be reduced and the adhesion between the interposer and the semiconductor element can be improved.

### BACKGROUND OF THE INVENTION

1. Field of the Invention

The present invention relates to a semiconductor device that achieves a reduction in stress from a sealing insulator added to a semiconductor element, suppression of warpage of the semiconductor element after being mounted on an interposer, and stable mounting of the semiconductor element on the interposer, and a method of manufacturing the semiconductor device.

2. Description of Related Art

For electronic equipment or mobile equipment, the demands for an increase in the number of functions, improvement in the performance, and reduction in cost have been growing year after year. Thus, further downsizing, an increase in the number of functions, improvement in the performance, and reduction in cost are essential also for semiconductor devices as key devices of electronic equipment or mobile equipment. In order to satisfy the above demands, in semiconductor devices, integration of components into a single chip and miniaturization of portions that are formed in a diffusion process using Low-k films have been pursued.

With the tendency toward miniaturization of portions that are formed in the diffusion process for producing the semiconductor device, fragile Low-k films have been adopted to reduce a dielectric constant of interlayer insulating films forming a semiconductor device. Thus, a semiconductor element receives a stress from a sealing insulator after the assembling process. As a result, the problem of peeling that occurs in the interlayer films in a Low-k film becomes noticeable.

In order to solve this problem, there has been proposed a semiconductor device configured by covering the surface of the semiconductor element with a resin film except terminals arranged on the semiconductor element in order to reduce the stress that a semiconductor element receives from a sealing insulator (e.g., see JP S59-87837 A).

FIG. 9 is a top view showing a configuration of a conventional semiconductor device. A semiconductor element 101 is disposed on an interposer 103, and a protective sheet 102 made of a resin is formed on the semiconductor element 101 in the area on which electrode pads 108 are not formed. Terminals 109 formed on the interposer 103 are connected to the electrode pads 108 through thin metal wires 105. By including a metal layer in the protective sheet 102, the semiconductor device becomes capable of stopping the entry of high frequency noise or an alpha ray.

In a method of manufacturing the conventional semiconductor device, after the semiconductor element 101 is mounted on the interposer 103, the protective film 102 is disposed on the semiconductor element 101 by heating and crimping the resin film covering the semiconductor surface except the terminals arranged on the semiconductor element 101.

However, the conventional semiconductor device has the following problems. With the tendency toward miniaturization of portions that are formed in the diffusion process for producing the semiconductor device, more fragile Low-k films have been adopted as the interlayer insulating films. Further, an increase in the number of functions causes an increase in the size of the semiconductor element. Due to these factors, the stress that the semiconductor element receives from the sealing insulator increases particularly at the corner portions, and the peeling of the interlayer insulating films at the corner portions of the semiconductor element increases. However, since the protective sheet is not formed on the conventional semiconductor element at the corner portions, the stress from the sealing insulator cannot be reduced. Thus, it is difficult to prevent the peeling of the interlayer insulating film at the corner portions of the semiconductor element.

Further, when the semiconductor element becomes thinner, warpage of the semiconductor element occurs after the semiconductor element is mounted on the interposer due to shrinkage of an adhesive for bonding the semiconductor element to the interposer. The protective sheet is formed on the semiconductor element surface except on the electrode pads in the conventional semiconductor element. However, when the electrode pads are arranged on the edge portions of the semiconductor element, support by the protective sheet does not reach the edge portions of the semiconductor device. Thus, the warp age occurs due to the shrinkage stress of the adhesive.

Moreover, if the number of lines of the electrode pads arranged on the edge portions of the semiconductor element is increased in the future, the area of the semiconductor element to which the protective sheet can be attached becomes small. As a result, it becomes difficult for the protective sheet to prevent peeling at the corner portions of the semiconductor element or the warpage.

Further, in the process of manufacturing the semiconductor device, a collet is used to pick up and mount the semiconductor element when mounting the semiconductor element on the interposer, and a collet having a size that does not come into contact with the electrode pads formed on the edge portions of the semiconductor element is selected. In the future, if the electrode pads are arranged in many lines so as to cope with an increase in the number of pins and narrower pitch due to the increase in the number of functions of the semiconductor element, the area on the semiconductor element surface except the area of the electrode pads becomes narrow, and accordingly, the size of the collet also becomes small. When the size of the collet is small, the pick-up property becomes unstable.

Further, when the size of the collet is small, a sufficient load does not transfer to the periphery of the semiconductor device at the time of mounting the semiconductor element on the interposer, causing a variation in the wet spreading property of the adhesive. This results in reduced bonding strength. Further, a variation occurs in the thickness of the adhesive, which increases an inclination of the semiconductor element. As a result, problems such as poor recognition and poor adhesion tend to occur in a wire bonding process. A variation in the wet spreading property of the adhesive and an inclination of the semiconductor element become noticeable as the size of the semiconductor element increases.

### SUMMARY OF THE INVENTION

Therefore, with forgoing in mind, it is an object of the present invention to provide a semiconductor device in which stress applied to a semiconductor element can be reduced and the adhesion between an interposer and the semiconductor element can be improved, and a method of manufacturing the semiconductor device.

The semiconductor device of the present invention includes: a semiconductor element including a circuit forming portion formed on a central region of a principal surface of the semiconductor element, and a plurality of electrode pads arranged on the principal surface outside the circuit forming portion; and a sealing insulator for sealing the semiconductor element. In order to solve the above problems, the semiconductor device of the present invention further includes a protective sheet formed on the principal surface of the semiconductor element so as to cover the circuit forming portion and at least some of the plurality of electrode pads.

In order to solve the above problems, a first method of manufacturing a semiconductor device of the present invention includes: attaching a protective sheet to a circuit forming surface of a semiconductor wafer on which a plurality of semiconductor elements are formed so as to cover circuit forming portions and at least some of electrode pads; dicing the semiconductor wafer by semiconductor element; mounting the semiconductor element on an interposer; electrically connecting the electrode pads formed on the semiconductor element and interposer terminals through thin metal wires; sealing the semiconductor element and the thin metal wires with a sealing insulator; and dicing the interposer by semiconductor element.

In order to solve the above problems, a second method of manufacturing a semiconductor device of the present invention includes: attaching protective sheets having a predetermined size to a circuit forming surface of a semiconductor wafer on which a plurality of semiconductor elements are formed so as to cover, in each of the semiconductor elements, a circuit forming portion and at least some of a plurality of electrode pads; dicing the semiconductor wafer by semiconductor element; mounting the semiconductor element on an interposer; electrically connecting the electrode pads formed on the semiconductor element and interposer terminals through thin metal wires; sealing the semiconductor element and the thin metal wires with a sealing insulator; and dicing the interposer by semiconductor element.

### BRIEF DESCRIPTION OF THE DRAWINGS

FIG. 1A is a top view showing a configuration of a semiconductor device according to Embodiment 1 of the present invention.

FIG. 1B is a cross-sectional view showing the semiconductor device shown in FIG. 1A, taken along a line A-A.

FIG. 2A is a cross-sectional view showing a step of manufacturing the semiconductor device according to Embodiment 1.

FIG. 2B is a cross-sectional view showing a step subsequent to the step shown in FIG. 2A.

FIG. 2C is a cross-sectional view showing a step subsequent to the step shown in FIG. 2B.

FIG. 2D is a cross-sectional view showing a step subsequent to the step shown in FIG. 2C.

FIG. 2E is a cross-sectional view showing a step subsequent to the step shown in FIG. 2D.

FIG. 2F is a cross-sectional view showing a step subsequent to the step shown in FIG. 2E.

FIG. 2G is a cross-sectional view showing a step subsequent to the step shown in FIG. 2F.

FIG. 2H is a cross-sectional view showing a step subsequent to the step shown in FIG. 2G.

FIG. 2I is a cross-sectional view showing a step subsequent to the step shown in FIG. 2H.

FIG. 3A is a top view showing a configuration of a semiconductor device according to Embodiment 2 of the present invention.

FIG. 3B is a cross-sectional view showing the semiconductor device shown in FIG. 3A, taken along a line B-B.

FIG. 4 is a top view showing a configuration of a semiconductor device according to Embodiment 3 of the present invention.

FIG. 5A is a cross-sectional view showing a step of manufacturing the semiconductor device according to Embodiment 3.

FIG. 5B is a cross-sectional view showing a step subsequent to the step shown in FIG. 5A.

FIG. 5C is a cross-sectional view showing a step subsequent to the step shown in FIG. 5B.

FIG. 5D is a cross-sectional view showing a step subsequent to the step shown in FIG. 5C.

FIG. 5E is a cross-sectional view showing a step subsequent to the step shown in FIG. 5D.

FIG. 5F is a cross-sectional view showing a step subsequent to the step shown in FIG. 5E.

FIG. 5G is a cross-sectional view showing a step subsequent to the step shown in FIG. 5F.

FIG. 5H is a cross-sectional view showing a step subsequent to the step shown in FIG. 5G.

FIG. 5I is a cross-sectional view showing a step subsequent to the step shown in FIG. 5H.

FIG. 5J is a cross-sectional view showing a step subsequent to the step shown in FIG. 5I.

FIG. 6 is a top view showing a configuration of a semiconductor device according to Embodiment 4 of the present invention.

FIG. 7 is a top view showing a configuration of a semiconductor device according to Embodiment 5 of the present invention.

FIG. 8 is a top view showing a configuration of a semiconductor device according to Embodiment 6 of the present invention.

FIG. 9 is a plan view showing a configuration of a conventional semiconductor device.

### DESCRIPTION OF THE PREFERRED EMBODIMENTS

The semiconductor device of the present invention includes the protective sheet formed on the principal surface of the semiconductor element so as to cover at least some of the plurality of electrode pads and the circuit forming portion. In this semiconductor device, since the protective sheet covers the electrode pads, an area on the semiconductor element covered with the protective sheet increases. Due to the increase in the area covered with the protective sheet, the stress that the corner portions of the semiconductor element receive from the sealing insulator is reduced. Thus, the peeling of interlayer insulating films in the semiconductor element caused by an external stress can be prevented.

Moreover, due to the increase in the area covered with the protective sheet, the protective sheet can prevent the semiconductor element from being bent due to the compression stress of the adhesive for fixing the semiconductor element to the interposer, and thus the stress applied to the semiconductor element can be reduced.

By covering the electrode pads with the protective sheet, a collet having a size larger than the area other than the electrode pads mounted on the semiconductor element can be used in the manufacturing process. Thus, the pick-up property of the semiconductor element and the wet spreading property of the adhesive can be stabilized, and the adhesion between the semiconductor element and the interposer can be improved.

The first method of manufacturing a semiconductor device of the present invention includes steps of attaching a protective sheet on a circuit forming surface of a semiconductor wafer on which a plurality of semiconductor elements are formed so as to cover at least some of electrode pads and circuit forming portions; dicing the semiconductor wafer by semiconductor element; mounting the semiconductor element on an interposer; electrically connecting the electrode pads formed on the semiconductor element and interposer terminals through thin metal wires; sealing the semiconductor element and the thin metal wires with a sealing insulator; and dicing the interposer by semiconductor element.

The second method of manufacturing a semiconductor device of the present invention includes steps of attaching protective sheets having a predetermined size on a circuit forming surface of a semiconductor wafer on which a plurality of semiconductor elements are formed so as to cover, in each of the semiconductor elements, at least some of a plurality of electrode pads and a circuit forming portion; dicing the semiconductor wafer by semiconductor element; mounting the semiconductor element on an interposer; electrically connecting the electrode pads formed on the semiconductor element and interposer terminals through thin metal wires; sealing the semiconductor element and the thin metal wires with a sealing insulator; and dicing the interposer by semiconductor element.

Using the first and the second methods of manufacturing a semiconductor device, a semiconductor device that produces the above effects can be manufactured.

The semiconductor device and the method of manufacturing the semiconductor device of the present invention, having the basic structure as described above, can be configured as follows.

That is, the semiconductor device may include: an interposer on which the semiconductor element is mounted; terminals arranged on the interposer; and thin metal wires for electrically connecting the electrode pads and the terminals. The thin metal wires may be sealed with the sealing insulator.

Some of the plurality of electrode pads may be exposed from the protective sheet.

The electrode pads may be arranged in at least two lines along a side of the semiconductor element.

Among the electrode pads arranged in at least two lines, at least the electrode pads in the outermost line may be exposed from the protective sheet. With this configuration, strong wire bonding properties can be ensured for the electrode pads exposed from the protective sheet. Further, since an excess protective sheet is not attached, the cost of the semiconductor device can be reduced. In the semiconductor element, the circuit forming portion side is referred to as inside and the side on which the electrode pads are formed is referred to as outside. The electrode pads in the outermost line are electrode pads that are arranged in the line farthermost from the circuit forming portion.

The protective sheet may include notches at portions on the electrode pads.

The protective sheet may include cutout portions having a bend at portions on the electrode pads. With this configuration, a contrast is enhanced easily due to the cutout portions when wire bonding equipment recognizes the positions of the electrode pads, and thus the wire bonding equipment can recognize the positions of the electrode pads easily. Further, by cutting off the protective sheet, the thin metal wires and the electrode pads can come into contact with each other easily in wire bonding, thereby enabling stable alloy formation.

The protective sheet may include cylindrical cutout portions at portions located on the electrode pads. Moreover, the electrode pads may be exposed from the cylindrical cutout portions, bumps may be formed on the electrode pads at the exposed portion, and the electrode pads and the thin metal wires may be connected to each other through the bumps. By forming the cutout portions in a cylindrical shape, the connectivity between the thin metal wires and the electrode pads can be improved when connecting the thin metal wires and the electrode pads through the bumps.

The opening width of the cutout portions may be in a range of 10 to 30 μm, which is recognizable by the wire bonding equipment. With this configuration, it is possible to prevent the entry of dirt and contamination of the electrode pads.

The semiconductor element may include fuses formed on the circuit forming portion, and the protective sheet may include openings formed at portions located on the fuses. With this configuration where the openings are formed at portions on the fuses, at the time of cutting off the fuses so as to repair a circuit or to adjust the device properties, the margin of laser condition for cutting off the fuses can be ensured, and the fuses can be cut off stably even in mass production.

In the first method of manufacturing a semiconductor device, electrode pads are covered with a protective sheet. Thus, the size of a collet can be selected regardless of the positions of the electrode pads. By using a large collet, it is possible to stabilize the pick-up property, and reduce the inclination of the semiconductor element when mounting the semiconductor element on an interposer, thereby stabilizing the wet spreading property of the adhesive.

The first method of manufacturing a semiconductor element may include: a step of adjusting the semiconductor wafer into a predetermined thickness between the step of attaching the protective sheet and the step of dicing the semiconductor wafer; and a step of attaching metal terminals to the backside of the surface of the interposer on which the semiconductor element is mounted between the step of sealing with the sealing insulator and the step of dicing the interposer.

In the second method of manufacturing a semiconductor device, it is possible to determine the size of the protective sheet coming into contact with a collet, on the basis of the size of the collet to be used. Therefore, the protective sheet does not become excessive and thus the cost can be reduced.

In the second method of manufacturing a semiconductor device, the electrode pads may be arranged in at least two lines along a side of the semiconductor element, and, in the step of attaching the protective sheet, the protective sheet may be attached such that, among the electrode pads arranged in at least two lines, at least the electrode pads in the outermost line are exposed.

The second method of manufacturing a semiconductor device may include, prior to the step of attaching the protective sheet, a step of attaching a back grinding protective sheet on the circuit forming surface of the semiconductor wafer, a step of adjusting the semiconductor wafer into a predetermined thickness, and a step of removing the back grinding protective sheet from the semiconductor wafer. The second method of manufacturing a semiconductor device may include a step of attaching metal terminals to the backside of the surface of the interposer on which the semiconductor element is mounted between the step of sealing with the sealing insulator and the step of dicing the interposer.

In the first and the second methods of manufacturing a semiconductor device, the surfaces of the semiconductor element and the interposer may be cleaned prior to the step of sealing with the sealing insulator. Since the surface of the protective sheet before the sealing step is contaminated due to the prior steps, the adhesion between the sealing insulator and the protective sheet weakens. This will cause peeling during a reliability test or a reflow process. With this configuration, by cleaning the surfaces of the semiconductor element and the interposer so as to remove contaminants before the sealing step, the adhesion between the protective sheet and the sealing insulator can be ensured, and the peeling between the sealing insulator and the protective sheet can be prevented.

In the step of connecting the electrode pads and the interposer terminals through the thin metal wires, ultrasonic vibration may be applied to the protective sheet on which notches are formed, and the thin metal wires may be inserted into the notches. In wire bonding, the thin metal wires and the electrode pads come into contact with each other easily from the notches formed on the protective sheet. Further, ultrasonic vibration is applied thereafter to increase the junction area while opening the notches of the protective sheet. Thus, it is possible to achieve stable alloy formation in wire bonding.

Hereinafter, embodiments of the semiconductor device according to the present invention will be described with reference to the drawings.

### Embodiment 1

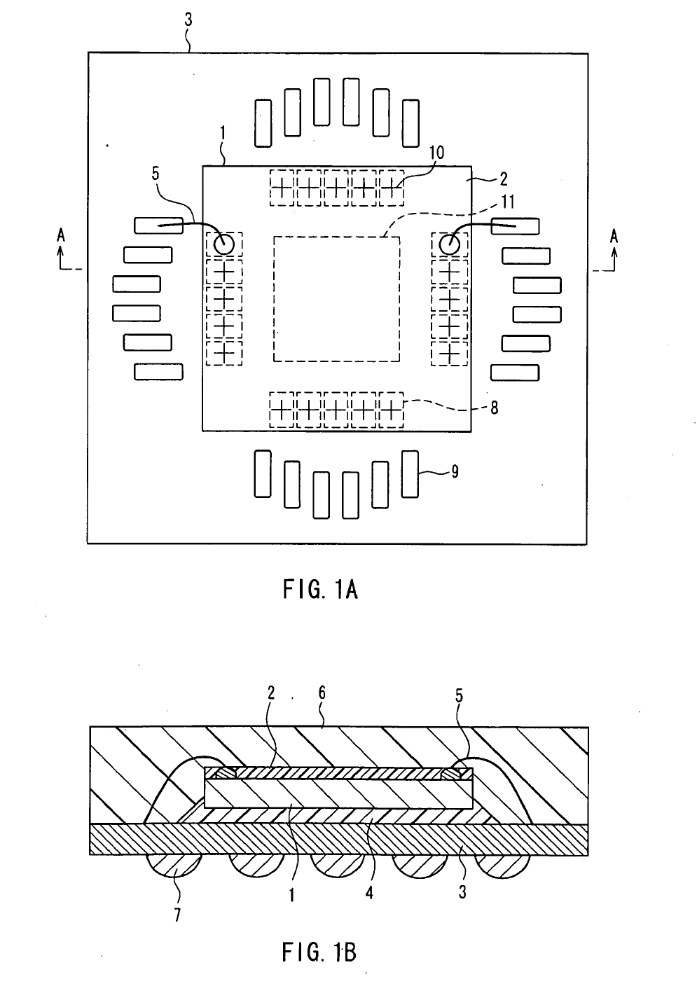

FIG. 1A is a top view showing a semiconductor device according to Embodiment 1 of the present invention, and FIG. 1B is a cross-sectional view showing the semiconductor device shown in FIG. 1A, taken along a line A-A. In FIG. 1A, the semiconductor device is shown without a sealing insulator 6 for the sake of clarity.

As shown in FIG. 1A, a circuit forming portion 11 is formed on the central region of a circuit forming surface (principal surface) of a semiconductor element 1. Electrode pads 8 are formed on the circuit forming surface outside the circuit forming portion 11. A protective sheet 2 is attached to the entire circuit forming surface of the semiconductor element 1. That is, the protective sheet 2 is disposed to cover the electrode pads 8 and the circuit forming portion 11 of the semiconductor element 1. Notches 10 are formed by making incisions in the protective sheet 2 at the portions on the electrode pads 8. First ends of thin metal wires 5 are inserted into the notches 10 and are connected to the electrode pads 8. There may be some notches 10 into which the thin metal wires 8 are not inserted, and they are used to connect a probe with the test electrode pads 8 in a test. The other ends of the thin metal wires 5 are connected to interposer terminals 9.

As shown in FIG. 1B, an adhesive 4 for fixing the semiconductor element 1 on the interposer 3 is applied on the backside of the circuit forming surface of the semiconductor element 1. A sealing insulator 6 seals the semiconductor element 1, the protective sheet 2, the adhesive 4, and the thin metal wires 5 on the interposer 3. Metal terminals 7 are attached to the backside of the surface of the interposer 3 on which the semiconductor element 1 is mounted, and are connected electrically to an external substrate (not shown). Further, the metal terminals 7 are connected to the interposer terminals 9 via through holes (not shown).

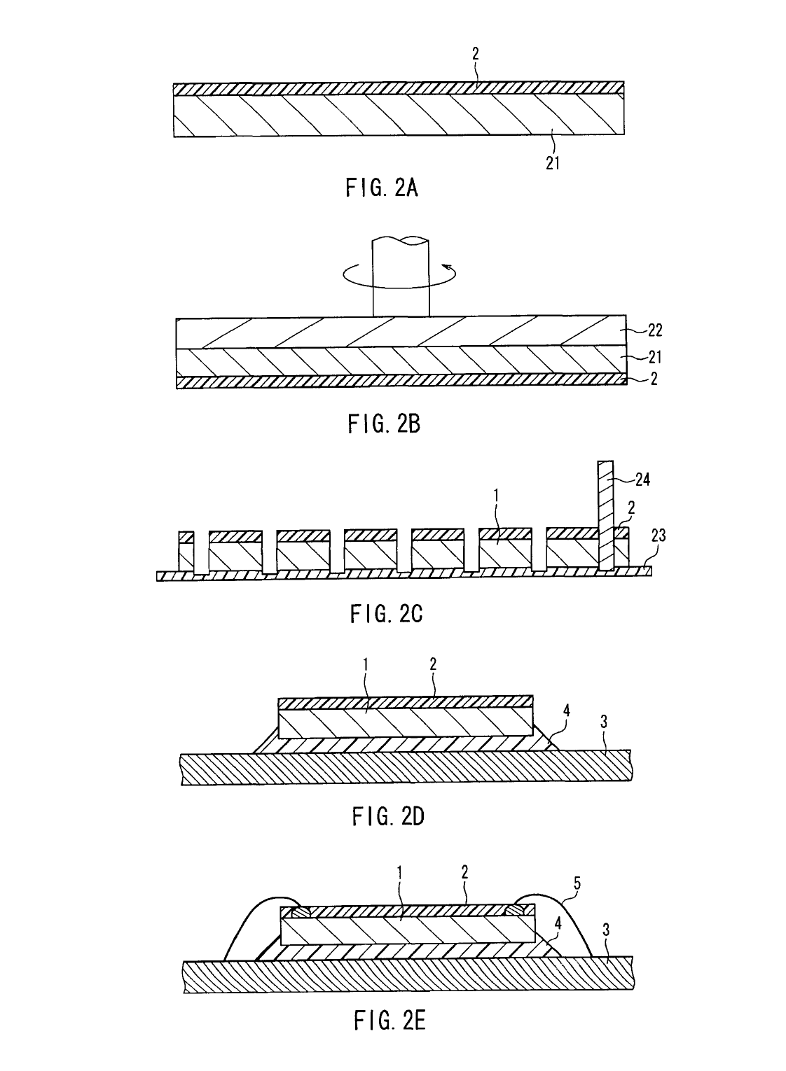

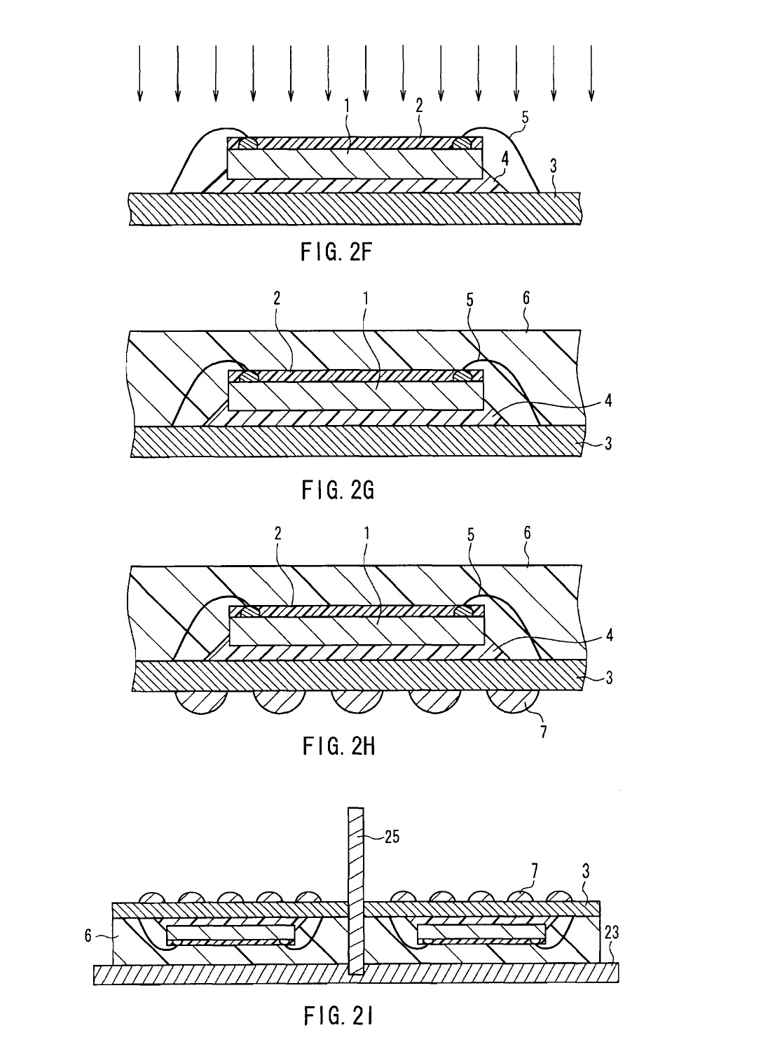

Next, a method of manufacturing the semiconductor device of this embodiment will be described. FIGS. 2A to 2I are cross-sectional views showing steps of manufacturing the semiconductor device of this embodiment. As shown in FIG. 2A, first, the protective sheet 2 is attached to a circuit forming surface of a semiconductor wafer 21. Circuits already have been formed on the semiconductor wafer 21. Then, as shown in FIG. 2B, with the protective sheet 2 being attached to the semiconductor wafer 21, the backside of the circuit forming surface of the semiconductor wafer 21 is brought into contact with a rotating grinder 22 so that the semiconductor wafer 21 is ground to a predetermined thickness. Next, as shown in FIG. 2C, the semiconductor wafer 21 to which the protective sheet 2 is attached is mounted on a dicing tape 23 such that the backside of the circuit forming surface adheres to the dicing tape 23. Subsequently, the semiconductor wafer 21 is diced by semiconductor element with a wafer dicing blade 24 to form the semiconductor element 1.

Next, as shown in FIG. 2D, the semiconductor element 1 including the protective sheet 2 attached to its circuit forming surface is picked up by a collet (not shown), and mounted on the interposer 3 by using the adhesive 4. Here, since the collet comes into contact with the protective sheet 2, it does not come into contact with the electrode pads 8 (see FIG. 1A). Therefore, a collet having a large size can be used, and thus the pick-up property can be stabilized.

Then, as shown in FIG. 2E, the electrode pads 8 and the interposer terminals 9 (see FIG. 1A) are connected electrically to each other through the thin metal wires 5. The connections between the electrode pads 8 and the thin metal wires 5 are achieved by the following steps. As shown in FIG. 1B, first, the notches 10 are formed on the protective sheet 2 at portions located on the electrode pads 8. Then, the thin metal wires 5 are inserted into the notches 10, and ultrasonic vibration is applied to junctions between the thin metal wires 5 and the electrode pads 8 so as to perform wire bonding. At that time, the notches 10 spread due to the ultrasonic vibration, and thus the thin metal wires 5 and the electrode pads 8 can be connected electrically to each other adequately. In this way, it is possible to connect the thin metal wires 5 and the electrode pads 8. The notches 10 may be formed on the protective sheet 2 before attaching the protective sheet 2 to the semiconductor wafer 21.

Next, as shown in FIG. 2F, the surfaces of the semiconductor element 1 and the interposer 3 are cleaned. Normally, a plasma treatment is performed as the cleaning step. Then, as shown in FIG. 2G, the semiconductor element 1, the protective sheet 2, the adhesive 4, and the thin metal wires 5 are sealed on the interposer 3 with the sealing insulator 6. Subsequently, as shown in FIG. 2H, the metal terminals 7 are attached to the backside of the surface of the interposer 3 on which the semiconductor element 1 is mounted. Finally, as shown in FIG. 2I, the dicing tape 23 is attached to the sealing insulator 6, and the interposer 3 is diced into separate semiconductor devices with a package dicing blade 25. Using the above steps, the semiconductor device is formed.

As described above, in the semiconductor device according to this embodiment, since the circuit forming surface of the semiconductor element 1 is covered entirely with the protective sheet 2, the fragile corner portions of the semiconductor element 1 can be protected and reinforced, and it is possible to prevent the peeling of interlayer insulating films. Furthermore, since the entire circuit forming surface of the semiconductor element 1 is covered with the protective sheet 2, it is possible to reduce the amount of warpage of the semiconductor element 1.

Moreover, since the electrode pads 8 are covered with the protective sheet 2, the contamination of the electrode pads 8 due to the contact between the electrode pads 8 and the collet can be prevented when picking up the semiconductor element 1 with the collet. Although the notches 10 are formed on the protective sheet 2 at portions located on the electrode pads 8, the collet and the electrode pads 8 do not come into direct contact with each other due to the thickness of the protective sheet 2. Further, since the incisions made to form the notches 10 are narrow, it is possible to prevent the entry of dirt.

Further, since the protective sheet 2 is formed on the electrode pads 8, the collet can be brought into contact with the entire circuit forming surface of the semiconductor element 1. Thus, a collet having a large size can be used. Therefore, when mounting the semiconductor element 1 on the interposer 3, a load is transferred sufficiently to the periphery of the semiconductor element and the wet spreading property of the adhesive or the like can be made uniform.

It is preferable that the thickness of the protective sheet 2 is in a range of 100 to 150 μm in order to reduce the amount of warpage of the semiconductor element 1 and to connect the electrode pads 8 and the thin metal wires 5.

### Embodiment 2

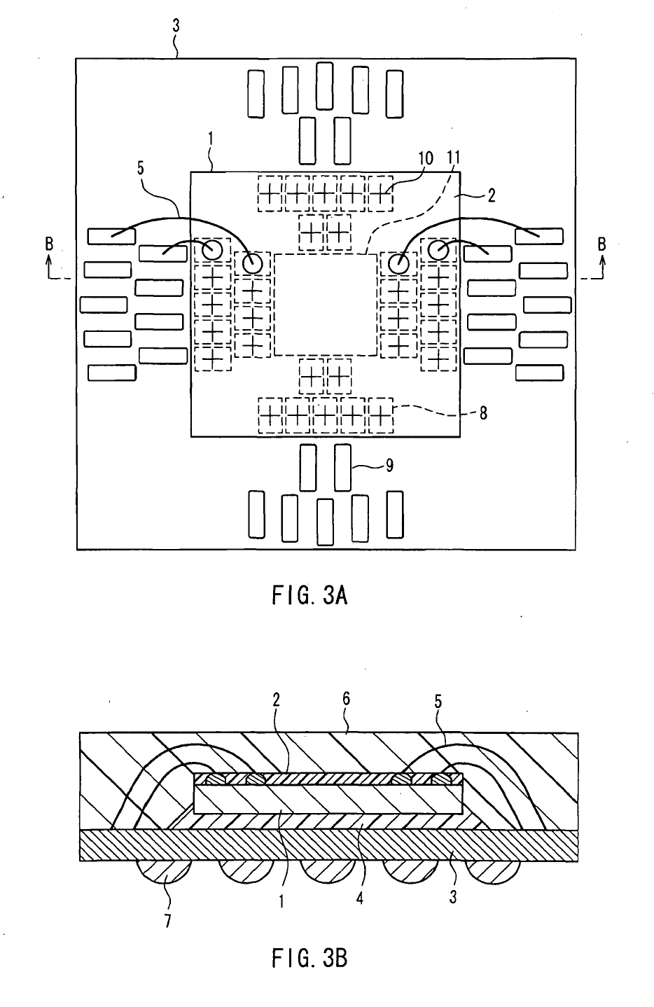

FIG. 3A is a top view showing a semiconductor device according to Embodiment 2 of the present invention, and FIG. 3B is a cross-sectional view of the semiconductor device shown in FIG. 3A, taken along a line B-B. The semiconductor device according to this embodiment has a configuration similar to the semiconductor device according to Embodiment 1 except that the electrode pads 8 and the interposer terminals 9 are arranged differently. Thus, in the semiconductor device according to this embodiment, the same components as in the semiconductor device according to Embodiment 1 are denoted by the same reference numerals, and part of the explanation will not be repeated.

As shown in FIG. 3A, on the semiconductor element 1 outside the circuit forming portion 11, the electrode pads 8 are arranged in two lines along the sides of the semiconductor element 1. When the number of the lines is increased to enhance the density of the electrode pads, the area on the semiconductor element 1 on which the electrode pads 8 are not formed becomes narrow. Similarly, the interposer terminals 9 also are arranged in two lines. The electrode pads 8 may be arranged in three lines or more.

In the conventional semiconductor device, a collet sized to avoid contact with electrode pads is used when picking up a semiconductor element. Thus, the size of the collet becomes very small in comparison with the size of the semiconductor element, causing the pick-up property of the collet to become unstable. Furthermore, when disposing the semiconductor element on the interposer, a load applied to the semiconductor element by the collet becomes unstable, resulting in instability of the wet spreading property of the adhesive. Consequently, a lack in the bonding strength between the semiconductor element and the interposer tends to occur.

In contrast, in the semiconductor device according to this embodiment, the electrode pads 8 are covered with the protective sheet 2. With this configuration, even if a collet having a size larger than the area on which the electrode pads 8 are not formed is used, the collet does not come into contact with the electrode pads 8. Thus, the electrode pads 8 are not contaminated by the collet, and a more stable pick-up property and wet spreading property can be obtained.

### Embodiment 3

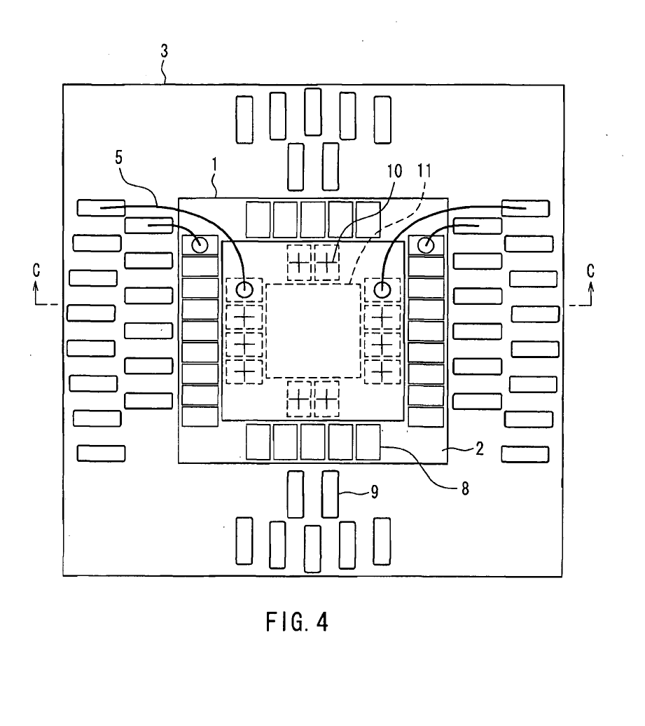

FIG. 4 is a top view showing a configuration of a semiconductor device according to Embodiment 3 of the present invention. The semiconductor device according to this embodiment has a configuration similar to the semiconductor device of Embodiment 2 except that the electrode pads 8 in the outermost line are exposed from the protective sheet 2. Thus, in the semiconductor device according to this embodiment, the same components as in the semiconductor device according to Embodiment 2 are denoted by the same reference numeral, and part of the explanation will not be repeated.

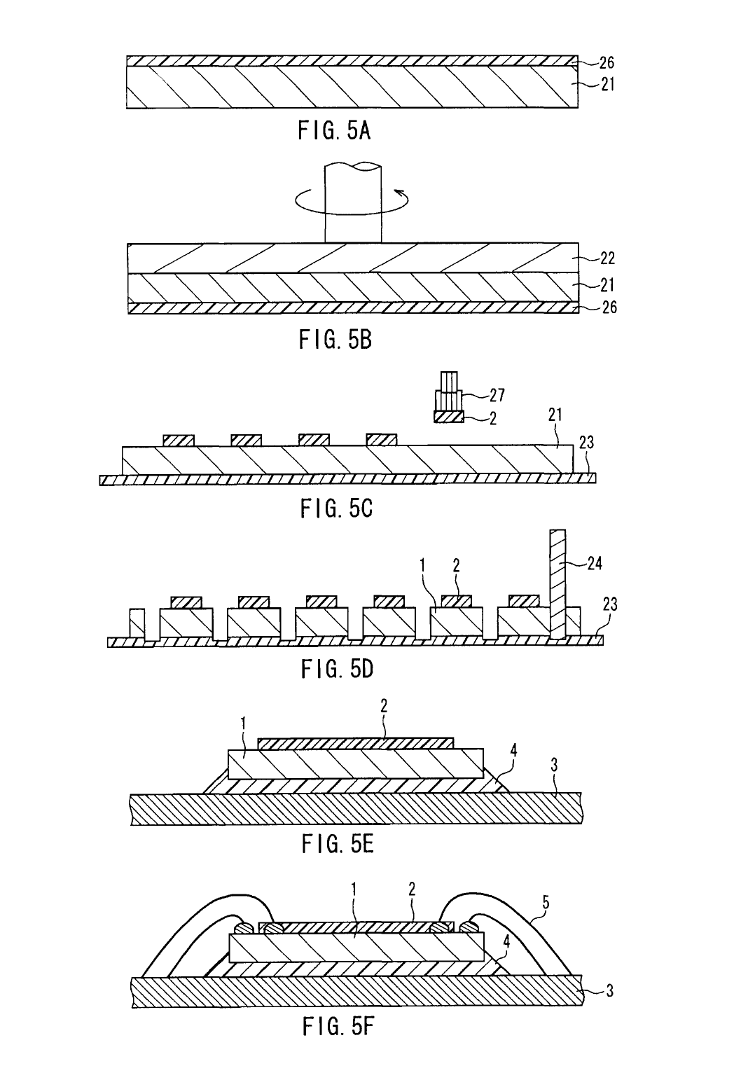

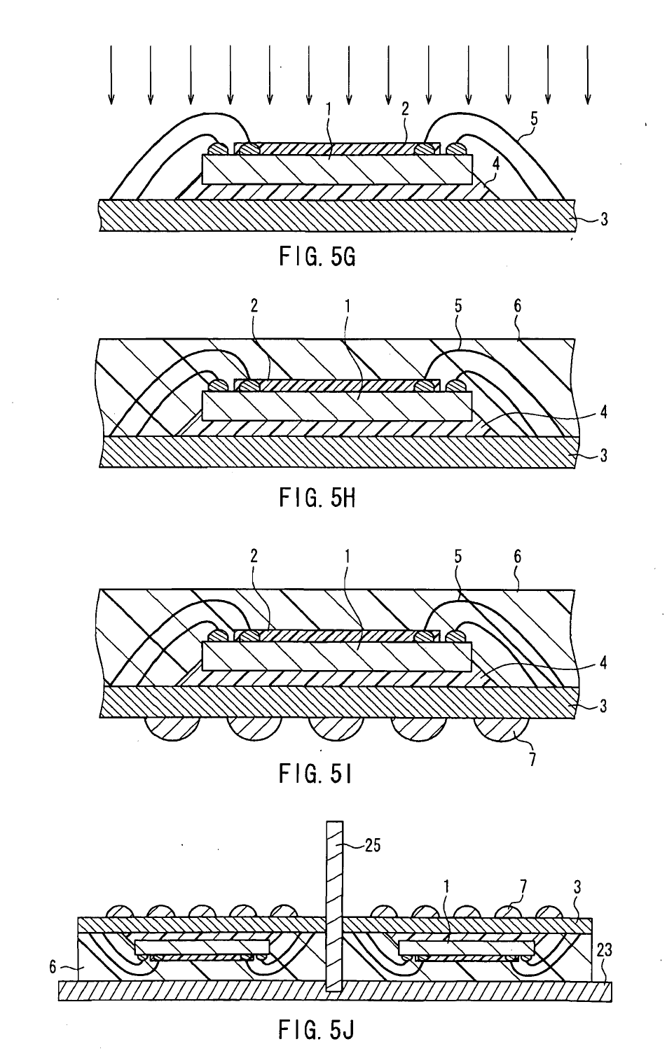

Hereinafter, a method of manufacturing the semiconductor device according to this embodiment will be described. FIGS. 5A to 5J are cross-sectional views showing steps of manufacturing the semiconductor device according to this embodiment. First, as shown in FIG. 5A, a back grinding protective sheet 26 is attached to the circuit forming surface of the semiconductor wafer 21. Then, as shown in FIG. 5B, the semiconductor wafer 21, with the back grinding protective sheet 26 being attached thereto, is ground into a predetermined thickness by bringing the backside of the circuit forming surface of the semiconductor wafer 21 into contact with the grinder 22, and rotating the grinder 22 to grind the semiconductor wafer 21.

Next, as shown in FIG. 5C, the back grinding protective sheet 26 is removed. Subsequently, the semiconductor wafer 21 is mounted on the dicing tape 23 such that the backside of the circuit forming surface adheres to the dicing tape 23. Then, by using a collet 27, the protective sheets 2 having a predetermined size are attached to the circuit forming surface of the semiconductor wafer 21 such that, in each of the semiconductor elements 1, the electrode pads 8 in the outermost line are exposed. Thereafter, as shown in FIG. 5D, the semiconductor wafer 21 to which the protective sheets 2 is attached is diced by the semiconductor element 1 with the wafer dicing blade 24. In this way, the semiconductor element 1 to which the protective sheet 2 is attached is formed.

Next, as shown in FIG. 5E, the semiconductor element 1 is removed from the dicing tape 23. The view in FIG. 5E is magnified relative to that in FIG. 5D. Then, the semiconductor element 1 including the protective sheet 2 attached to its circuit forming surface is picked up by the collet (not shown), and mounted on the interposer 3 by using the adhesive 4. Furthermore, a load is applied to the semiconductor element 1 by the collet so as to improve the adhesion between the semiconductor element 1 and the adhesive 4. Subsequently, as shown in FIG. 5F, the electrode pads 8 and the interposer terminals 9 shown in FIG. 4 are connected electrically to each other through the thin metal wires 5.

Next, as shown in FIG. 5G, the surfaces of the semiconductor element 1 and the interposer 3 are cleaned by performing a plasma treatment, for example. Then, as shown in FIG. 5H, the semiconductor element 1, the protective sheet 2, the adhesive 4, and the thin metal wires 5 are sealed on the interposer 3 with the sealing insulator 6. Subsequently, as shown in FIG. 5I, the metal terminals 7 are attached to the backside of the surface of the interposer 3 on which the semiconductor element 1 is mounted. Then, as shown in FIG. 5J, the dicing tape 23 is attached to the sealing insulator 6, and the interposer 3 and the sealing insulator 6 are diced into separate semiconductor devices with the package dicing blade 25. By the above steps, the semiconductor device is formed.

Since the electrode pads 8 in the outermost line are exposed from the protective sheet 2, the thin metal wires 5 and the electrode pads 8 in the outermost line can form an alloy together in wire bonding, and their connections can be strengthened. Moreover, it is possible further to narrow only the pitches between the electrode pads 8 exposed from the protective sheet 2.

The protective sheet 2 having a size that matches the size of the collet can be used. Thus, it is possible to reduce the cost of the semiconductor device.

### Embodiment 4

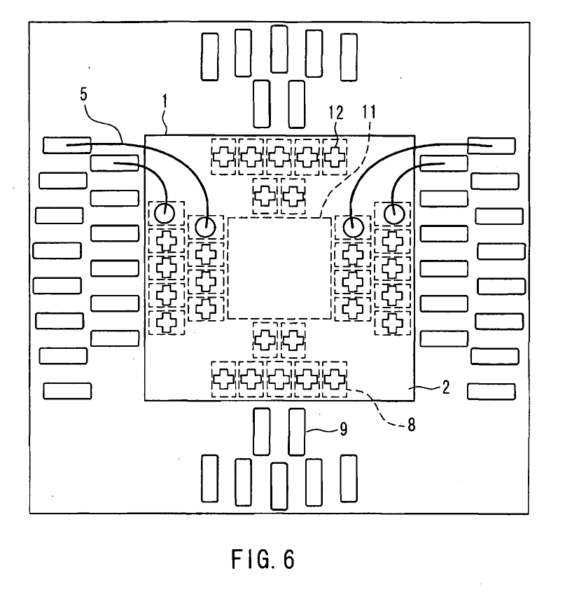

FIG. 6 is a top view showing a configuration of a semiconductor device according to Embodiment 4 of the present invention. The semiconductor device according to this embodiment has a configuration similar to the semiconductor device according to Embodiment 2 except that cutout portions 12 are formed instead of the notches 10 (see FIG. 3). Thus, in the semiconductor device according to this embodiment, the same components as in the semiconductor device according to Embodiment 2 are denoted by the same reference numeral, and part of the explanation will not be repeated.

Each of the cutout portions 12 on the protective sheet 2 is formed by cutting off the protective sheet 2 in the shape of a cross so that wire bonding equipment easily can recognize the positions at which the electrode pads 8 are formed. The opening width of the cutout portions 12 is about 10 to 30 μm. When the width of the cutout portions 12 is within this range, it is possible to reduce the contamination of the electrode pads 8 due to the entry of dirt through the cutout portions 12.

As described above, by forming the cutout portions 12 on the protective sheet 2, the positions of the electrode pads 8 will be recognized easily, and thus it is possible to prevent misalignment, and a short circuit and a poor contact caused by the misalignment.

The shape of the cutout portions 12 is not limited to a cross shape, as long as the positions of the electrode pads 8 become clear and the entry of dirt can be reduced. For example, the cutout portion 12 may be shaped to have a bend such as an L-shape, or it can be shaped to have a corner.

### Embodiment 5

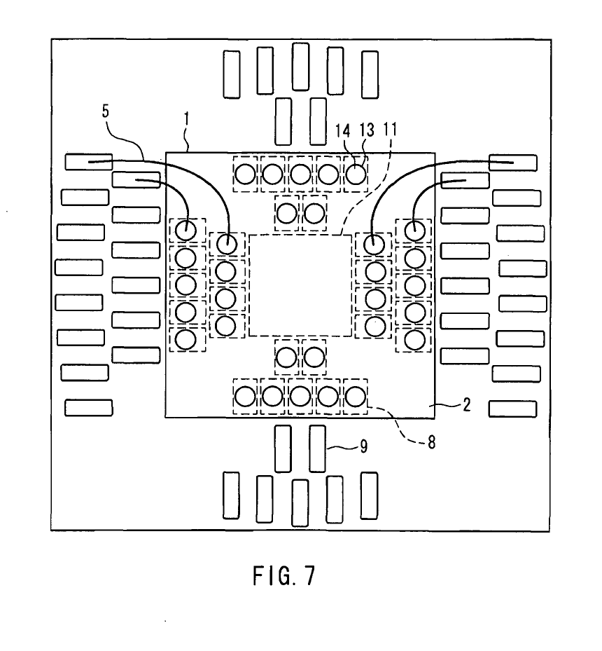

FIG. 7 is a top view showing a configuration of a semiconductor device according to Embodiment 5 of the present invention. The semiconductor device according to this embodiment has a configuration similar to the semiconductor device according to Embodiment 4 except that, instead of the cutout portions 12 (see FIG. 6), circular cutout portions 13 are formed. Thus, in the semiconductor device according to this embodiment, the same components as in the semiconductor device according to Embodiment 4 are denoted by the same reference numeral, and part of the explanation will not be repeated.

The circular cutout portions 13 formed on the protective sheet 2 are cylindrical openings formed on the protective sheet 2 at portions located on the electrode pads 8. Circular bumps 14 are formed on the electrode pads 8, and the bumps 14 are exposed through the circular cutout portions 13. The bumps 14 connect the electrode pads 8 and the thin metal wires 5.

When connecting the thin metal wires 5 and the electrode pads 8, in a bump method, ultrasonic vibration with lower power in comparison with the ultrasonic used in a wire bonding method is used to ensure the height of the bumps 14. However, low-power ultrasonic vibration cannot open the protective sheet 2 sufficiently when the protective sheet 2 is positioned under the bumps 14. As a result, the thin metal wires 5 and the bump 14 cannot form an alloy together sufficiently, causing poor adhesion between the electrode pads 8 and the thin metal wires 5. Thus, by forming the circular cutout portions 13 having the same diameter as the desired diameter of the bumps 14, an alloy can be formed stably in the bump method.

In order to reduce the entry of dirt, it is preferable that the diameter of the circular cutout portions 13 is 30 μm or less.

### Embodiment 6

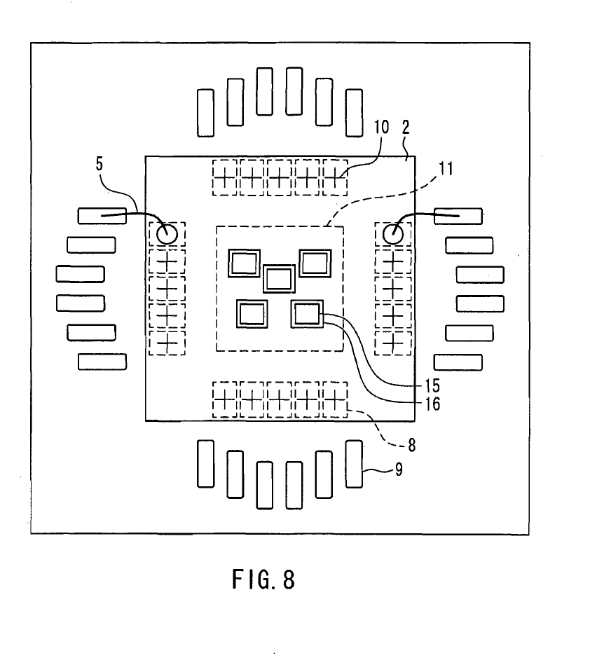

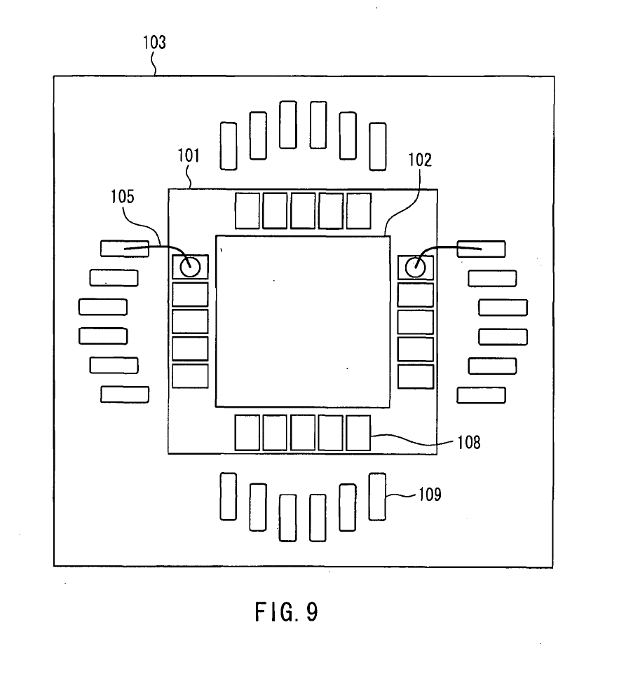

FIG. 8 is a top view showing a configuration of a semiconductor device according to Embodiment 6 of the present invention. The semiconductor device according to this embodiment has a configuration similar to the semiconductor device according to Embodiment 1 in principle except the components described below. Thus, in the semiconductor device according to this embodiment, the same components as in the semiconductor device according to Embodiment 1 are denoted by the same reference numeral, and part of the explanation will not be repeated.

Redundant circuits (not shown) are formed on the circuit forming portion 11. A fuse 15 is formed on each of the redundant circuits. By cutting off the fuses 15, the redundant circuits are cut off and the properties of the semiconductor element 1 can be adjusted. Openings 16 are formed by cutting off the protection sheet 2 at portions on the fuses 15. It is preferable that the openings 16 have a shape that is easily recognizable. In order to cut off the fuses 15, the openings 16 are formed in a size to allow passage of a laser beam.

The conventional semiconductor device in which a protective sheet is formed on a semiconductor element has the following problems. The semiconductor element is provided with fuses on the circuit forming portion so as to repair a circuit with redundant circuits after a test, or to adjust the device properties. The fuses are cut off with a laser beam in accordance with the test results. However, when the fuses are covered with a resin film, they cannot be cut off with a laser beam, or the process margin at the time of cutting off the fuses with a laser beam becomes small, thereby problems may be caused in mass production.

In the semiconductor device according to this embodiment, the openings 16 are formed at the portions located on the fuses 15. With this configuration, the above problems can be solved, and the process margin at the time of cutting off the fuses with a laser beam can be widened.

The invention may be embodied in other forms without departing from the spirit of essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A semiconductor device comprising:
a semiconductor element including a circuit forming portion formed on a central region of a principal surface of the semiconductor element, and a plurality of electrode pads arranged on the principal surface outside the circuit forming portion; and
a sealing insulator for sealing the semiconductor element,
wherein the semiconductor device further comprises a protective sheet formed on the principal surface of the semiconductor element so as to cover at least some of the plurality of electrode pads and the circuit forming portion.

2. The semiconductor device according to claim 1 further comprising:
an interposer on which the semiconductor element is mounted;
terminals arranged on the interposer; and
thin metal wires for electrically connecting the electrode pads and the terminals,
wherein the thin metal wires are sealed with the sealing insulator.

3. The semiconductor device according to claim 1, wherein some of the plurality of electrode pads are exposed from the protective sheet.

4. The semiconductor device according to claim 1, wherein the electrode pads are arranged in at least two lines along a side of the semiconductor element.

5. The semiconductor device according to claim 4, wherein, among the electrode pads arranged in at least two lines, at least the electrode pads in an outermost line are exposed from the protective sheet.

6. The semiconductor device according to claim 1, wherein the protective sheet includes notches at portions located on the electrode pads.

7. The semiconductor device according to claim 1, wherein the protective sheet includes cutout portions having a bend at portions located on the electrode pads.

8. The semiconductor device according to claim 1, wherein the protective sheet includes cylindrical cutout portions located on the electrode pads.

9. The semiconductor device according to claim 8, wherein
the electrode pads are exposed through the cylindrical cutout portions,
bumps are formed on the electrode pads at the exposed portion, and
the electrode pads and the thin metal wires are connected to each other through the bumps.

10. The semiconductor device according to claim 7, wherein an opening width of the cutout portions is 30 μm or less.

11. The semiconductor device according to claim 1, wherein
the semiconductor element includes fuses formed on the circuit forming portion, and
the protective sheet includes openings formed at portions on the fuses.

12. A method of manufacturing a semiconductor device, comprising steps of:
attaching a protective sheet to a circuit forming surface of a semiconductor wafer on which a plurality of semiconductor elements are formed so as to cover at least some of electrode pads and circuit forming portions;
dicing the semiconductor wafer by semiconductor element;
mounting the semiconductor element on an interposer;
electrically connecting the electrode pads formed on the semiconductor element and interposer terminals through thin metal wires;
sealing the semiconductor element and the thin metal wires with a sealing insulator; and
dicing the interposer by semiconductor element.

13. The method of manufacturing a semiconductor device according to claim 12 further comprising: a step of adjusting the semiconductor wafer into a predetermined thickness between the step of attaching the protective sheet and the step of dicing the semiconductor wafer; and a step of attaching metal terminals to the backside of the surface of the interposer on which the semiconductor element is mounted between the step of sealing with the sealing insulator and the step of dicing the interposer.

14. A method of manufacturing a semiconductor device, comprising steps of:
attaching protective sheets having a predetermined size to a circuit forming surface of a semiconductor wafer on which a plurality of semiconductor elements are formed so as to cover, in each of the semiconductor elements, a circuit forming portion and at least some of a plurality of electrode pads;
dicing the semiconductor wafer by semiconductor element;
mounting the semiconductor element on an interposer;
electrically connecting the electrode pads formed on the semiconductor element and interposer terminals through thin metal wires;
sealing the semiconductor element and the thin metal wires with a sealing insulator; and
dicing the interposer by semiconductor element.

15. The method of manufacturing a semiconductor device according to claim 14,
wherein the electrode pads are arranged in at least two lines along a side of the semiconductor element, and
in the step of attaching the protective sheet, the protective sheet is attached such that, among the electrode pads arranged in at least two lines, at least the electrode pads in the outermost line are exposed.

16. The method of manufacturing a semiconductor device according to claim 14, further comprising, prior to the step of attaching the protective sheet,
a step of attaching a back grinding protective sheet to the circuit forming surface of the semiconductor wafer,
a step of adjusting the semiconductor wafer into a predetermined thickness, and
a step of removing the back grinding protective sheet from the semiconductor wafer and,
a step of attaching metal terminals on the backside of the surface of the interposer on which the semiconductor element is mounted between the step of sealing with the sealing insulator and the step of dicing the interposer.

17. The method of manufacturing a semiconductor device according to claim 12, wherein the surfaces of the semiconductor element and the interposer are cleaned prior to the step of sealing with the sealing insulator.

18. The method of manufacturing a semiconductor device according to claim 14, wherein the surfaces of the semiconductor element and the interposer are cleaned prior to the step of sealing with the sealing insulator.

19. The method of manufacturing a semiconductor device according to claim 12, wherein in the step of connecting the electrode pads and the interposer terminals through the thin metal wires, ultrasonic is applied to a protective sheet on which notches are formed, and the thin metal wires are inserted into the notches.

20. The method of manufacturing a semiconductor device according to claim 14, wherein in the step of connecting the electrode pads and the interposer terminals through the thin metal wires, ultrasonic vibration is applied to a protective sheet on which notches are formed, and the thin metal wires are inserted into the notches.
